(19) United States
(12) Patent Application Publication
(10) Pub. No.: US 2010/0127294 A1
(43) Pub. Date: May 27, 2010

(54) SIDE VIEW TYPE LIGHT-EMITTING DIODE PACKAGE STRUCTURE, AND MANUFACTURING METHOD AND APPLICATION THEREOF

(75) Inventors: Shiming CHEN, TAINAN COUNTY (TW); Hsingmao WANG, TAINAN COUNTY (TW)

Correspondence Address: BRIAN M. MCINNIS, 12th Floor, Ruttonjee House, 11 Duddell Street, Hong Kong, HK

(73) Assignee: CHI MEI LIGHTING TECHNOLOGY CORP., Tainan County (TW)

(21) Appl. No.: 12/557,524

(22) Filed: Sep. 11, 2009

(30) Foreign Application Priority Data
Nov. 25, 2008 (TW) 97145554

(51) Int. Cl. H01L 33/00

(52) U.S. Cl. 257/98; 438/27; 257/E33.056; 257/E33.067

(57) ABSTRACT

A side view type light-emitting diode package structure, and a manufacturing method and an application thereof are described. The side view type light-emitting diode package structure includes a silicon base, a first and a second conductive leads and at least one light-emitting diode chip. The silicon base includes a first cavity defining a light-extracting surface of the package structure. The first and the second conductive leads are respectively disposed at least on a portion and another portion of the first cavity and extend to an outer surface of the silicon base. The first and the second conductive leads are electrically isolated from each other. The light-emitting diode chip includes a first and second electrodes electrically connected to the first and the second conductive leads respectively, wherein the surface on the outer side of the silicon base is substantially perpendicular to the light-extracting surface.

### RELATED APPLICATIONS

This application claims priority to Taiwan Application Serial Number 97145554, filed Nov. 25, 2008, which is herein incorporated by reference.

### FIELD OF THE INVENTION

The present invention relates to a light-emitting diode (LED) package structure, and more particularly to a side view type light-emitting diode package structure and its applications in a light-emitting diode light bar and a light-emitting diode backlight module.

### BACKGROUND OF THE INVENTION

With the trend towards energy conservation and environmental protection, light-emitting diodes have become the most conspicuous energy saving light sources in light sources replacing the currently existing light sources. Among the light-emitting diode light sources, surface mounting type (SMT) light-emitting diodes are widely applied. The typical light-emitting diode chips generally cannot transform majority of the input electric energy into light energy, and the electric energy is mostly lost in the form of thermal energy, so that the transformation efficiency of the light-emitting diode chips is poor. If the heat produced during the operation of the light-emitting diode chip cannot be effectively eliminated, the junction temperature of the light-emitting diode chip is greatly increased, thereby reducing the luminous efficiency of the light-emitting diode chip and decreasing the reliability of the light-emitting diode chip. Therefore, how to resolve the heat-dissipating problem has become an important subject of the development of the light-emitting diode device.

Typically, high-power light-emitting diodes are referred to 1 W or more than 1 W light-emitting diodes. A larger current is needed to input into a high-power light-emitting diode chip, so that the heat-dissipating problem is more important. Refer to FIG. 1. FIG. 1 illustrates a cross-sectional view of a conventional high-power SMT light-emitting diode package structure. A light-emitting diode package structure 100 mainly includes a light-emitting diode chip 104, a package base 102, a lead frame 106, a wire 108 and a package encapsulant 110. The package base 102 is formed of polyphthalamide (PPA) by an injection-molding method. Typically, the lead frame 106 is combined with the package base 102 during the injection-molding of the package base 102. The lead frame 106 further includes a heat sink 114 in addition to two electrically separated leads 112. The heat sink 114 is combined with one of the leads 112, and the heat sink 114 is much thicker than the leads 112 to improve the heat-dissipating ability. The package base 102 includes a cavity 116, wherein a bottom of the cavity 116 exposes one lead 112 of the lead frame 106 and a portion of the heat sink 114.

The light-emitting diode chip 104 is disposed in the cavity 116 of the package base 102 and is located on the exposed portion of the heat sink 114 of the lead frame 106, so that the heat produced by the light-emitting diode chip 104 can be rapidly conducted via the heat sink 114. In addition, two electrodes of the light-emitting diode chip 104 are electrically connected to the two leads 112 of the lead frame 106 by, for example, using the wire 108 or a flip-chip method. The package encapsulant 110 is filled into the cavity 116 of the package base 102 and covers the light-emitting diode chip 104 and the wire 108.

The heat sink 114 can enhance the heat-dissipating effect of the light-emitting diode package structure 100, so that the light-emitting diode package structure 100 can be applied in a high-power light-emitting diode device of more than 1 W. However, the conventional high-power light-emitting diode package structure 100 still has the following disadvantages. The light-emitting diode package structure 100 is a top view type light-emitting diode package structure and has a larger size, so that the light-emitting diode package structure 100 cannot be applied in a backlight module with a thin light guide plate. In addition, the difference between the thermal conduction coefficients of the material of the package base 102 and the semiconductor material of the light-emitting diode chip 104 is large, so that the connection of the package base 102 and the light-emitting diode chip 104 is easily broken by the thermal expansion, thereby reducing the reliability of the light-emitting diode package structure 100. Furthermore, the surface of the package base 102 usually needs cleaning in the process and the polyphthalamide surface of the package base 102 is easily damaged after the package base 102 is cleaned by plasma, so that thereby decreasing the reflectivity of the surface of the package base 102 and thereby affecting the intensity of the emitted of light. Moreover, with the design of the heat sink 114, the thickness of the lead frame 106 and the heat sink 114 is irregular and the difference of the thickness is large, so that the process of manufacturing the lead frame 106 together with the heat sink 114 is complicated, and a scrap issue is caused, thereby being adverse for reducing the cost.

### SUMMARY OF THE INVENTION

Therefore, one aspect of the present invention is to provide a side view type light-emitting diode package structure and a method for manufacturing the same, which uses silicon as the material of a package base. The thermal expansion coefficient of silicon is closer to that of semiconductor material of a light-emitting diode chip, so that it can prevent the connection of the light-emitting diode chip and the silicon package base from being affected by the thermal expansion to increase the reliability of the side view type light-emitting diode package structure.

Another aspect of the present invention is to provide a side view type light-emitting diode package structure and a method for manufacturing the same, in which a silicon package base has a superior heat-conducting ability, so that a conventional lead frame, which includes a metal heat sink and has a highly irregular thickness, is not needed, thereby greatly reducing the difficulty of manufacturing the lead frame and solving the scrap issue that occurs in the process of manufacturing the lead frame.

Still another aspect of the present invention is to provide a side view type light-emitting diode package structure and its applications in a light-emitting diode light bar and a light-emitting diode backlight module, in which a package base has a superior heat-conducting property, so that the package structure is suitable for a low-power light-emitting diode chip and a high-power light-emitting diode chip of more than 1 W.

Further another aspect of the present invention is to provide a side view type light-emitting diode package structure and its applications in a light-emitting diode light bar and a light-emitting diode backlight module, in which a surface of a cavity of a silicon package base formed by using a semiconductor process is smooth, so that the surface of the cavity can be used as a reflective surface directly, the reflective effect of the reflective surface is not affected by the plasma cleaning, and the package base has a better reflective effect than the conventional plastic base.

Still further another aspect of the present invention is to provide a side view type light-emitting diode package structure and its applications in a light-emitting diode light bar and a light-emitting diode backlight module. The light-emitting diode package structure is the side view type, so that the width of the light-emitting diode light bar and the thickness of the side-edged type backlight module can be effectively reduced.

According to the aforementioned aspects, the present invention provides a side view type light-emitting diode package structure. The side view type light-emitting diode package structure includes a silicon base, a first conductive lead, a second conductive lead and a first light-emitting diode chip. The silicon base includes a first cavity, and the first cavity defines a light-extracting surface of the side view type light-emitting diode package structure. The first conductive lead is disposed at least on a portion of the first cavity and extends to an outer surface of the silicon base. The second conductive lead is disposed at least on another portion of the first cavity and extends to the outer surface of the silicon base, wherein the first conductive lead and the second conductive lead are electrically isolated from each other. The first light-emitting diode chip includes a first electrode and a second electrode, and the first electrode and the second electrode are electrically connected to the first conductive lead and the second conductive lead respectively, wherein the outer surface of the silicon base is substantially perpendicular to the light-extracting surface.

According to a preferred embodiment of the present invention, the silicon base is a one-piece structure.

According to the aforementioned aspects, the present invention provides a method for manufacturing a side view type light-emitting diode package structure including the following steps. A silicon base is provided, wherein the silicon base includes a first cavity and a second cavity respectively set in a first surface and a second surface of the silicon base adjacent to each other, and the first cavity defines a light-extracting surface of the side view type light-emitting diode package structure. At least two conductive leads are formed to cover the first cavity and to extend on the second cavity, wherein the conductive leads are electrically isolated from each other, and the light-extracting surface is substantially perpendicular to the portions of the conductive leads located in the second cavity. At least one light-emitting diode chip is disposed in the first cavity, wherein the light-emitting diode chip includes two electrodes electrically connected to the conductive leads respectively. A package encapsulant is formed to cover the light-emitting diode chip.

According to a preferred embodiment of the present invention, the method further includes forming an insulation layer to at least cover a bottom surface of the first cavity between the step of providing the silicon base and the step of forming the conductive leads.

According to another aspect, the present invention provides a method for manufacturing a side view type light-emitting diode package structure including the following steps. A silicon sub-base is provided, wherein the silicon sub-base includes a first surface and a second surface adjacent to each other, and the silicon sub-base includes a first cavity located in the second surface. At least two conductive leads are formed to cover and to extend on the first surface of the silicon sub-base and a surface of the first cavity, wherein the conductive leads are electrically isolated from each other. A silicon cavity portion is disposed on the first surface of the silicon sub-base, wherein the silicon sub-base and the silicon cavity portion define a second cavity, and the second cavity exposes a portion of each conductive lead. The second cavity defines a light-extracting surface of the side view type light-emitting diode package structure, and the light-extracting surface is substantially perpendicular to the portions of the conductive leads located in the first cavity. At least one light-emitting diode chip is disposed in the second cavity, wherein the light-emitting diode chip includes two electrodes electrically connected to the conductive leads respectively. A package encapsulant is formed to cover the light-emitting diode chip.

According to a preferred embodiment of the present invention, the step of disposing the silicon cavity portion further includes using an adhesion layer to connect the silicon cavity portion and the silicon sub-base.

According to still another aspect, the present invention provides a light-emitting diode light bar and its application in a light-emitting diode backlight module. The light-emitting diode backlight module includes a carrier, a light guide plate and at least one light-emitting diode light bar. The light guide plate is disposed on the carrier. The light-emitting diode light bar is disposed beside a light-entering surface of the light guide plate. The light-emitting diode light bar includes a circuit board and at least one side view type light-emitting diode package structure. The side view type light-emitting diode package structure includes a silicon base, a first conductive lead, a second conductive lead and a first light-emitting diode chip. The silicon base includes a first cavity, and the first cavity defines a light-extracting surface of the side view type light-emitting diode package structure. The first conductive lead is disposed at least on a portion of the first cavity and extends to an outer surface of the silicon base. The second conductive lead is disposed at least on another portion of the cavity and extends to the outer surface of the silicon base, wherein the first conductive lead and the second conductive lead are electrically isolated from each other. The first conductive lead and the second conductive lead are located on a plane surface of the circuit board, and the light-extracting surface is substantially perpendicular to the plane surface of the circuit board. The first light-emitting diode chip includes a first electrode and a second electrode, and the first electrode and the second electrode are electrically connected to the first conductive lead and the second conductive lead respectively.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 illustrates a cross-sectional view of a conventional high-power SMT light-emitting diode package structure;

FIG. 2 is a three-dimensional drawing of a side view type light-emitting diode package structure in accordance with a preferred embodiment of the present invention;

FIG. 3 illustrates a cross-sectional view of the side view type light-emitting diode package structure taken along a cross-sectional line A-A′ of FIG. 2;

FIG. 4A through FIG. 4G are schematic flow diagrams showing a process of manufacturing a side view type light-emitting diode package structure in accordance with a preferred embodiment of the present invention;

FIG. 5 is a three-dimensional drawing of a side view type light-emitting diode package structure in accordance with another preferred embodiment of the present invention;

FIG. 6 illustrates a cross-sectional view of the side view type light-emitting diode package structure taken along a cross-sectional line B-B′ of FIG. 5;

FIG. 7A through FIG. 7F are schematic flow diagrams showing a process of manufacturing a side view type light-emitting diode package structure in accordance with another preferred embodiment of the present invention;

FIG. 8 is a schematic diagram showing a light-emitting diode backlight module in accordance with a preferred embodiment of the present invention; and

FIG. 9 is a schematic diagram showing a light-emitting diode backlight module in accordance with another preferred embodiment of the present invention.

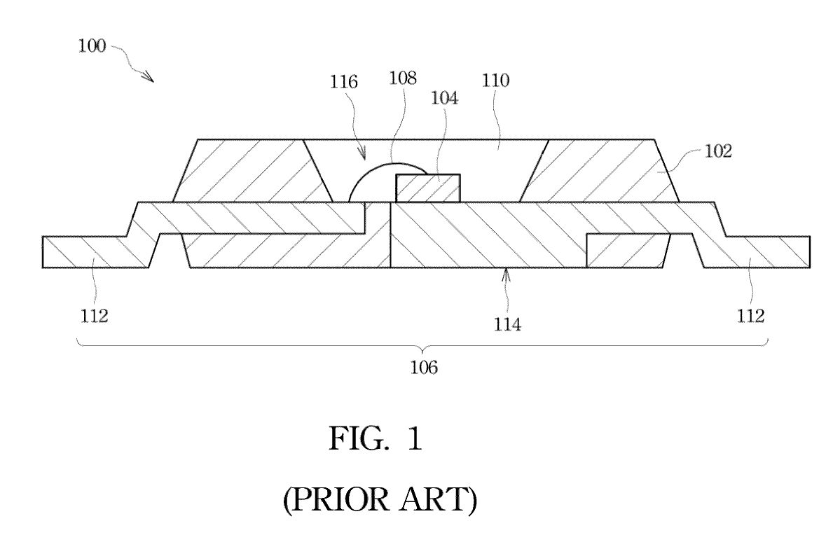

### DETAILED DESCRIPTION OF THE PREFERRED EMBODIMENT

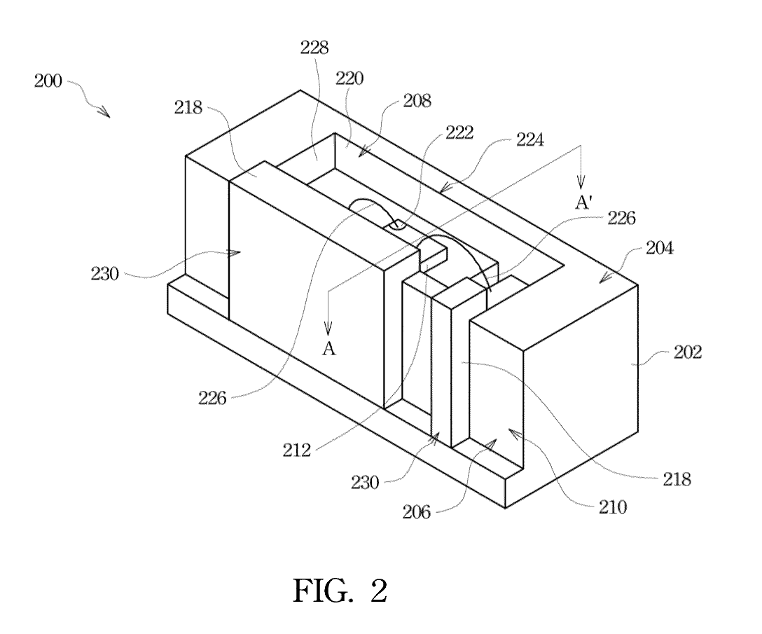

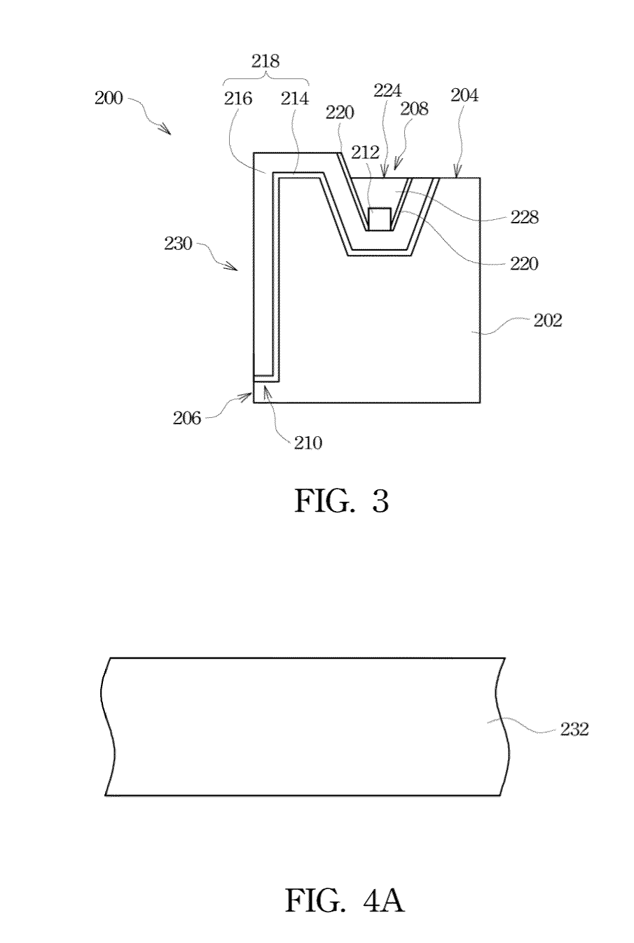

Refer to FIG. 2 and FIG. 3. FIG. 2 and FIG. 3 respectively illustrate a three-dimensional drawing of a side view type light-emitting diode package structure in accordance with a preferred embodiment of the present invention and a cross-sectional view of the side view type light-emitting diode package structure taken along a cross-sectional line A-A′ of FIG. 2. A side view type light-emitting diode package structure 200 mainly includes a silicon base 202, two conductive leads 218, one or more light-emitting diode chips 212 and a package encapsulant 228. In the present exemplary embodiment, the silicon base 202 is a one-piece structure. In one embodiment, the silicon base 202 includes adjacent surfaces 204 and 206. The silicon base 202 includes a first cavity 208, and the first cavity 208 is set in the surface 204 of the silicon base 202, wherein the first cavity 208 defines a light-extracting surface 224 of the side view type light-emitting diode package structure 200. In the present exemplary embodiment, the silicon base 202 further includes a second cavity 210, wherein the second cavity 210 is set in the surface 206 of the silicon base 202. Such as shown in FIG. 2 and FIG. 3, the conductive leads 218 both cover the first cavity 208 in the surface 204 of the silicon base 202 and both extend to cover the second cavity 210 in the surface 206, wherein the conductive leads 218 are electrically isolated from each other. Each conductive lead 218 may be a single-layered structure made of a single material layer, or may be a multi-layered structure formed by stacking at least two material layers. Such as shown in FIG. 3, in the present exemplary embodiment, each conductive lead 218 includes a seed layer 214 and an electroplating layer 216 stacked on the silicon base 202 in sequence, so that each conductive lead 218 is a multi-layered structure. The material of the seed layer 214 may be Cu, Au, Ag or Ni, for example. The material of the electroplating layer 216 may be Cu, Ag or Ni, for example.

As shown in FIG. 3, the light-emitting diode chip 212 is disposed in the first cavity 208 of the silicon base 202, and the light-emitting diode chip 212 may be disposed on the conductive lead 218, for example. In one embodiment, in order to provide better insulation between the silicon base 202 and the light-emitting diode chip 212, an insulation layer (not shown) may be selectively formed on the silicon base 202 to dispose the insulation layer between the conductive leads 218 and the silicon base 202. The material of the insulation layer may be silicon dioxide, silicon nitride or ceramics, for example. The light-extracting surface 224 of the side view type light-emitting diode package structure 200 is substantially perpendicular to the surface 206 on an outer side of the silicon base 202. In the present exemplary embodiment, the side view type light-emitting diode package structure 200 has one single light-emitting diode chip 212. In other exemplary embodiments, the side view type light-emitting diode package structure 200 may include a plurality of light-emitting diode chips 212. Each light-emitting diode chip 212 includes two electrodes 222, wherein the electrodes 222 have different conductivity types. For example, one of the electrodes 222 is P-type, and the other of the electrodes 222 N-type. In the present exemplary embodiment, the light-emitting diode chip 212 has a horizontal electrode structure, i.e. the two electrodes 222 of the light-emitting diode chip 212 are located on the same side of the light-emitting diode chip 212. In accordance with the design of multiple light-emitting diode chips 212, the side view type light-emitting diode package structure 200 may include more than two conductive leads, such as several conductive leads 218. In one embodiment, all electrodes 222 respectively correspond to the conductive leads 218, and the electrodes 222 may be electrically connected to the corresponding conductive leads 218 via wires 226 respectively. In another embodiment, a common cathode or common anode design may be adopted, so that the side view type light-emitting diode package structure 200 has more electrodes 222 than conductive leads 218, and each one of a part of conductive leads 218 is electrically connected to at least two of the electrodes 222 via the wires 226. The light-emitting diode chips 212 may have the same color tone, for example, all light-emitting diode chips 212 may be blue. The light-emitting diode chips 212 may also have different color tones, for example, the light-emitting diode chips 212 may include two green light-emitting diode chips, one red light-emitting diode chip and one blue light-emitting diode chip.

In one exemplary embodiment, according to the brightness requirement of the product, the side view type light-emitting diode package structure 200 may selectively include a reflective layer 220 covering a side surface of the first cavity 208 of the silicon base 202, such as shown in FIG. 3. The reflective layer 220 may be a metal reflective layer, a nonmetal reflective layer or a metal layer/nonmetal layer compound structure, for example. In one embodiment, the side surface of the first cavity 208 may be directly used as a reflective surface without setting a reflective layer. The package encapsulant 228 is filled in the first cavity 208 of the silicon base 202 and covers the light-emitting diode chip 212, and preferably covers the wire 226 simultaneously. In one exemplary embodiment, the package encapsulant 228 may be mixed with fluorescent powder. The choice of the fluorescent powder may be made according to the desired color of the light of the device and the color of the light emitted by the light-emitting diode chip 212. In one embodiment, when the desired color of the light of the device is white, and the light-emitting diode chip 212 emits blue light, the package encapsulant 228 may be mixed with yellow fluorescent powder, or red-green fluorescent powder.

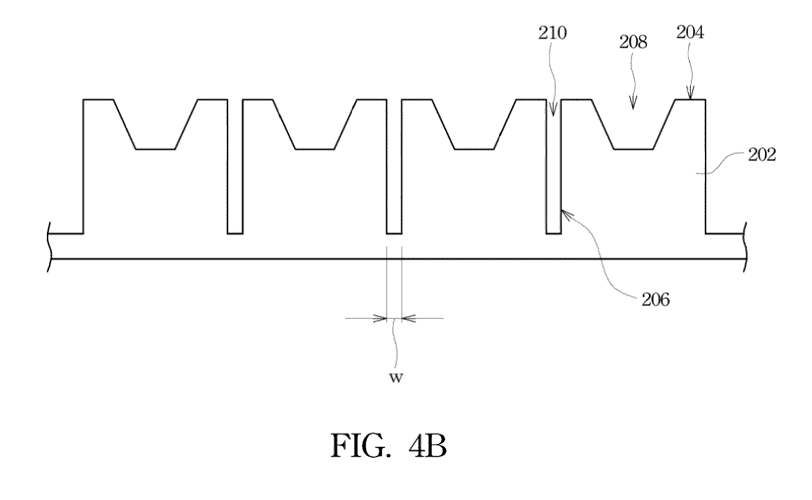

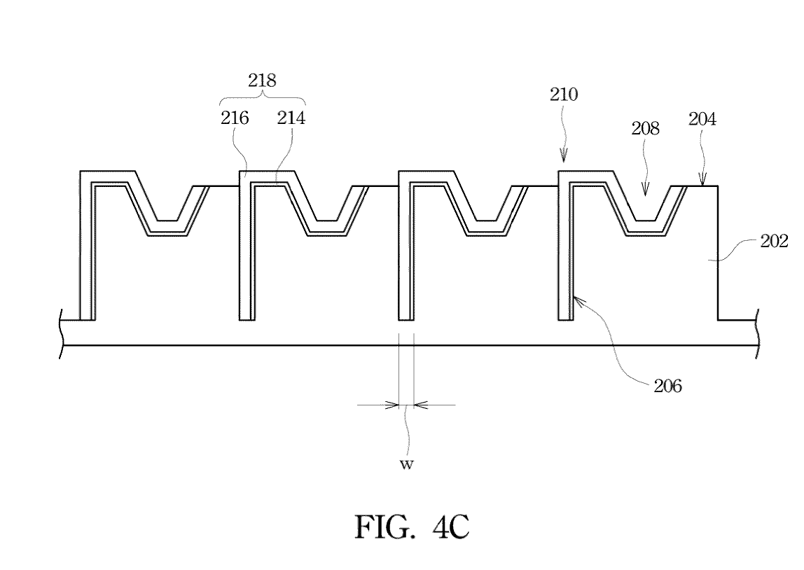

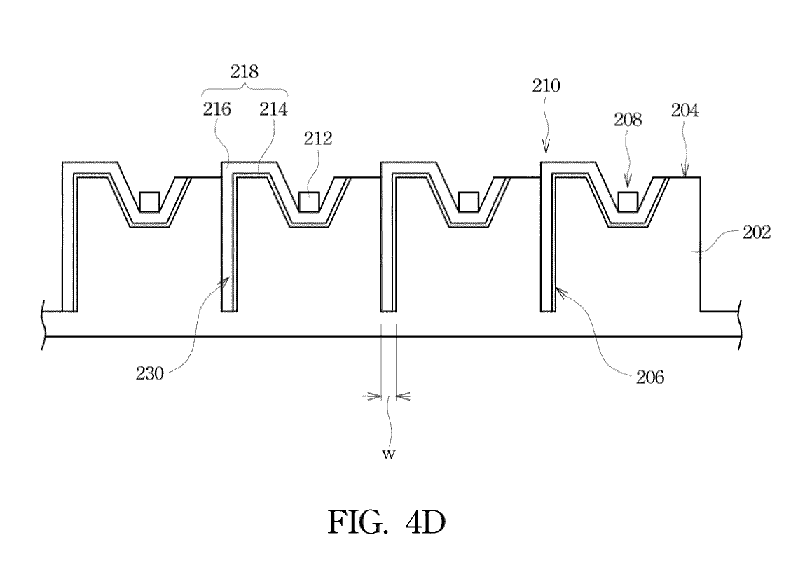

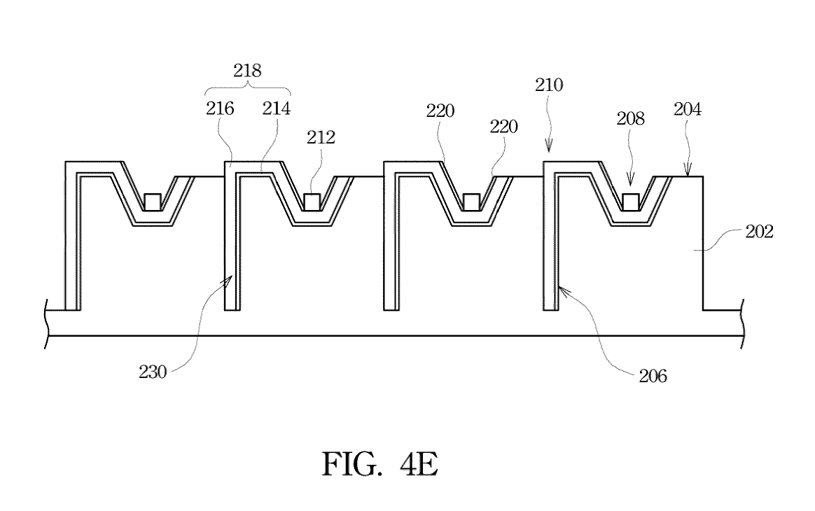

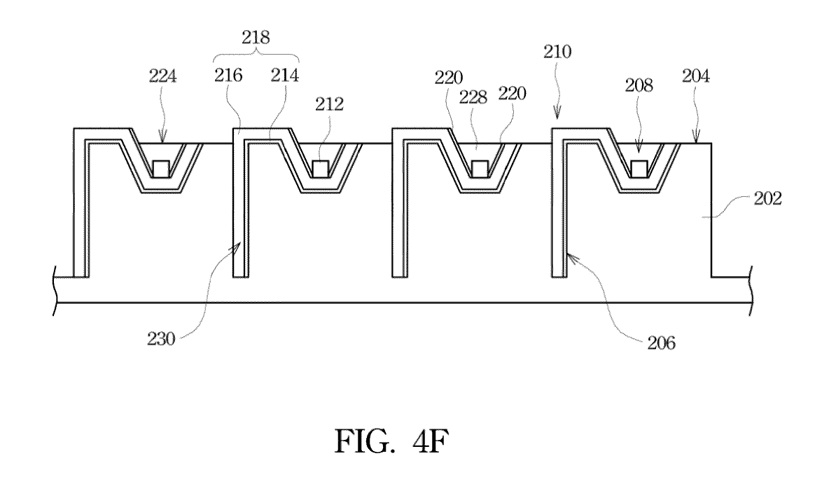

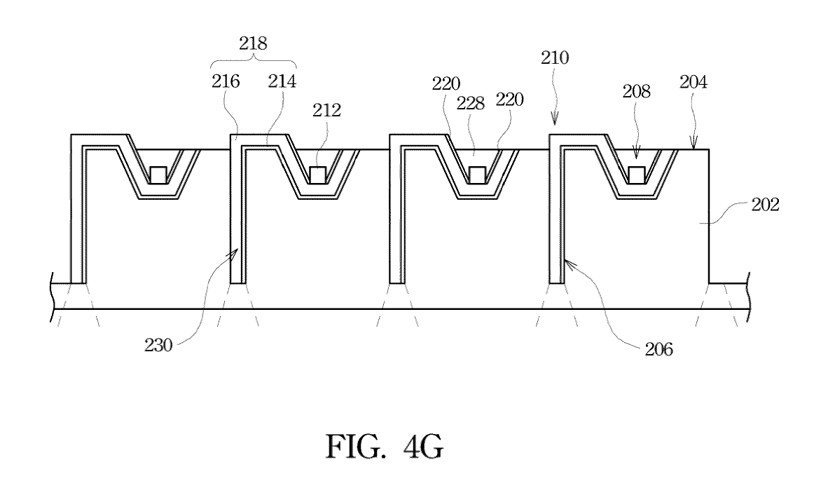

Refer to FIG. 4A through FIG. 4G. FIG. 4A through FIG. 4G are schematic flow diagrams showing a manufacturing process for a side view type light-emitting diode package structure in accordance with a preferred embodiment of the present invention. In one exemplary embodiment, in the manufacture of the side view type light-emitting diode package stricture 200, a silicon substrate 232 is provided, such as shown in FIG. 4A. Next, such as shown in FIG. 4B, first and second cavities 208 and 210 are defined in the silicon substrate 232 by, for example, a photolithography and etching technique. The silicon substrate 232 may be defined by, for example, a wet etching process to form the first cavity 208 in the surface 204 of each silicon base 202. The wet etching process may use KOH or HF as the etchant. In another embodiment, a reactive ion etching (RIE) process may be used to form the first cavity 208 in the surface 204 of the silicon base 202. One or more second cavities 210 may be formed in the silicon substrate 232 by, for example, a reactive ion etching process to define a plurality of silicon bases 202. The second cavity 210 is located in the surface 206 of the silicon base 202, and the second cavity 210 has a width w. The thickness of the conductive lead 218 (referring to FIG. 4C) formed sequentially may be controlled by controlling the width w of the second cavity 210.

In order to provide a better insulation property between the light-emitting diode chip 212 (referring to FIG. 4D) sequentially disposed and the silicon base 202, an insulation layer (not shown) may be selectively formed on a bottom of the first cavity 208 of the silicon base 202 or on the entire outer surface of the silicon base 202. In the formation of the insulation layer, silicon dioxide or silicon nitride may be formed by, for example, a deposition method or a furnace thermal oxidation method, or a ceramic layer may be formed by, for example, a deposition method. A better heat-conducting effect can be provided by using the ceramic layer as the insulation layer.

Referring to FIG. 4C, at least two conductive leads 218 are formed to cover the first cavity 208 in the surface 204 of the silicon base 202, and to extend and cover the second cavity 210 in another surface 206. The conductive leads 218 are electrically isolated from each other. In one embodiment, each conductive lead 218 may be a single-layered structure. In one exemplary embodiment, each conductive lead 218 may be a multi-layered structure. For example, a thin seed layer 214 is firstly formed to cover the silicon base 202 by a pattern defining technique, a sputtering or evaporation deposition method in the semiconductor process. The seed layer 214 includes two or more portions defined by a semiconductor pattern defining technique, and the portions are electrically isolated from each other. Then, an electroplating layer 216 is formed on the seed layer 214 by using the seed layer 214 as the base and using, for example, an electroplating method, to complete the conductive leads 218 electrically isolated from each other. The thickness of the seed layer 214 may be adjusted according to the process and may be controlled between about hundreds of Å and about thousands of Å. The material of the seed layer 214 may be, for example, Cu, Au, Ag or Ni. The thickness of the electroplating layer 216 may be controlled by using the width w of the second cavity 210 defined in the silicon base 202, and is preferably slightly less than the width w to benefit the sequential cutting and dividing process of the package base. The material of the electroplating layer 216 may be, for example, Cu, Ag or Ni. In the present exemplary embodiment, the conductive leads 218 are formed by an electroplating method to prevent the material stress issue caused by bending the metal material many times in the prior art.

Then, simultaneously referring to FIG. 4D and FIG. 2, one or more light-emitting diode chips 212 are disposed in the first cavity 208 of each silicon base 202. Each light-emitting diode chip 212 includes two electrodes 222 of different conductivity types, such as shown in FIG. 2. Then, the electrodes 222 are electrically connected to the corresponding conductive leads 218 by a flip-chip method or a wire bonding method with the use of the wires 226 shown in FIG. 2, for example. Each conductive lead 218 is electrically connected to one or more electrodes 222 correspondingly.

Next, such as shown in FIG. 4E, the reflective layer 220 may be selectively formed to cover the side surface of the first cavity 208 of the silicon base 202 according to the brightness requirement of the product. In one embodiment, the side surface of the first cavity 208 can be directly used as the reflective surface without forming a reflective layer. Then, such as shown in FIG. 4F, the package encapsulant 228 is formed to fill in the first cavity 208 of the silicon base 202 and to cover the light-emitting diode chip 212 and the wire 226. In one embodiment, the package encapsulant 228 may be mixed with fluorescent powder, such as yellow fluorescent powder or red-green fluorescent powder. In the present exemplary embodiment, the light-extracting surface 224 of the side view type light-emitting diode package structure 200 is substantially perpendicular to the portion of the conductive lead 218 extending to the surface 206 on the outer side of the silicon based 202.

Then, referring to FIG. 4G, the silicon material connected between two adjacent silicon bases 202 is separated by, for example a backside etching process, to separate the side view type light-emitting diode package structures 200, so as to form the structure shown in FIG. 2 and FIG. 3. In another embodiment, the structure shown in FIG. 2 and FIG. 3 can be obtained through separating the side view type light-emitting diode package structures 200 by a split process.

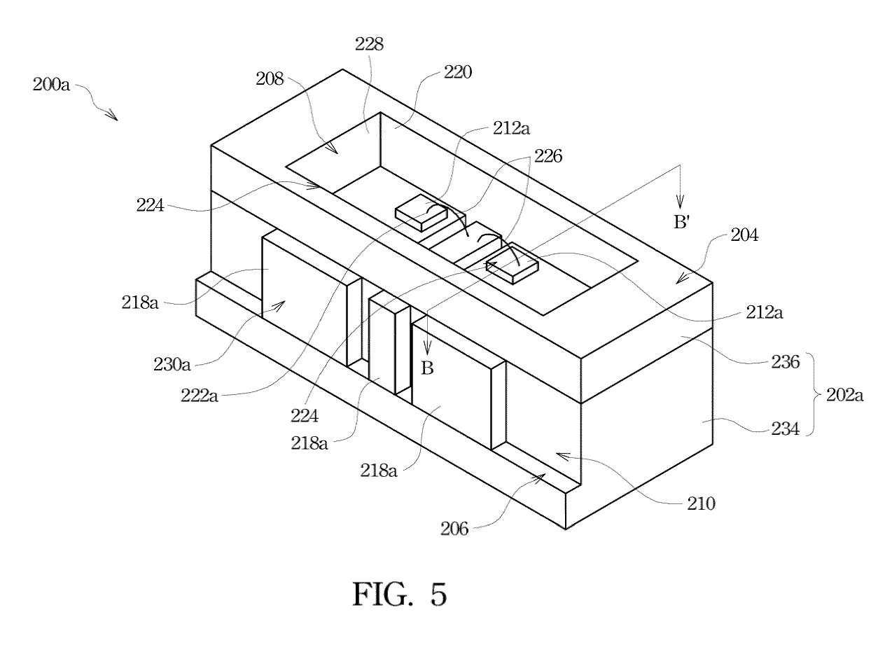

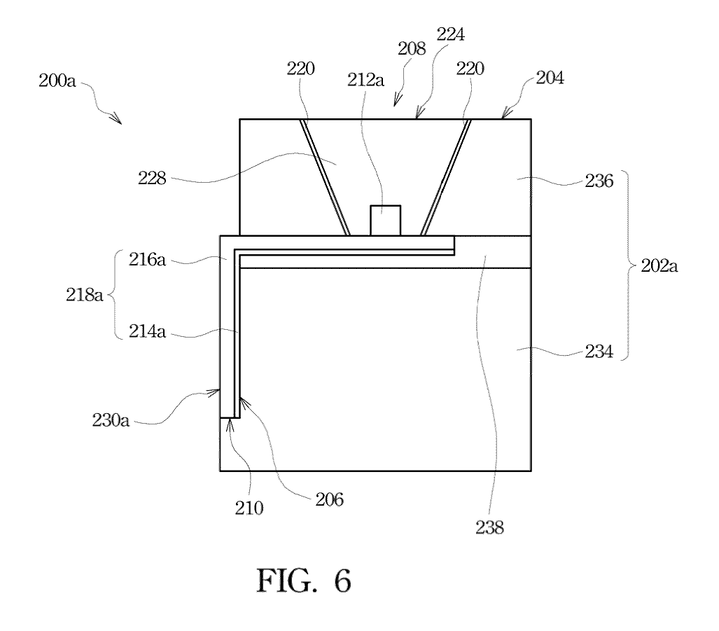

Refer to FIG. 5 and FIG. 6. FIG. 5 and FIG. 6 respectively illustrate a three-dimensional drawing of a side view type light-emitting diode package structure in accordance with another preferred embodiment of the present invention, and a cross-sectional view of the side view type light-emitting diode package structure taken along a cross-sectional line B-B′ of FIG. 5. A side view type light-emitting diode package structure 200a mainly includes a silicon base 202a, two conductive leads 218a, one or more light-emitting diode chips 212a and a package encapsulant 228. In the present exemplary embodiment, the silicon base 202a is not a one-piece structure, and is formed by stacking a silicon sub-base 234 and a silicon cavity portion 236. The silicon sub-base 234 is connected to a bottom surface of the silicon cavity portion 236. In one embodiment, an adhesion layer (not shown) may be used to connect the silicon sub-base 234 and the silicon cavity portion 236. The material of the adhesion layer may be polymer or adhesion glue, such as epoxy. In one embodiment, the silicon base 202a includes surfaces 204 and 206 adjacent to each other. The silicon base 202a includes a first cavity 208, and the first cavity 208 is set in the surface 204 of the silicon base 202a. In the present exemplary embodiment, such as shown in FIG. 6, the silicon base 202a further includes a second cavity 210, wherein the second cavity 210 is set in the surface 206 of the silicon base 202a. In the present exemplary embodiment, the first cavity 208 is defined by the silicon sub-base 234 and the silicon cavity portion 236 cooperatively, and the first cavity 208 defines a light-extracting surface 224 of the side view type light-emitting diode package structure 202a. In one embodiment, the light-extracting surface 224 of the side view type light-emitting diode package structure 202a is substantially perpendicular to the surface 206 on the outer side of the silicon base 202a. Such as shown in FIG. 5 and FIG. 6, the first cavity 208 of the silicon base 202a exposes the conductive leads 218a and the conductive leads 218a extend to cover the second cavity 210 in the surface 206, wherein the conductive leads 218a are electrically isolated from each other. Each conductive lead 218a may be a single-layered structure made of a single material layer, or may be a multi-layered structure formed by stacking at least two material layers. Such as shown in FIG. 6, in the present exemplary embodiment, each conductive lead 218a includes a seed layer 214a and an electroplating layer 216a stacked on the silicon base 202a in sequence, so that each conductive lead 218a is a multi-layered structure. The material of the seed layer 214a may be Cu, Au, Ag or Ni, for example. The material of the electroplating layer 216a may be Cu, Ag or Ni, for example.

Such as shown in FIG. 6, in one embodiment, in order to provide better insulation between the silicon base 202a and the light-emitting diode chip 212a, an insulation layer 238 may be selectively formed on the silicon sub-base 234 of the silicon base 202a, wherein the insulation layer 238 is located between the silicon sub-base 234 and the silicon cavity portion 236 and under the conductive leads 218a. In another embodiment, the insulation layer 238 may be located between the entire conductive leads 218a and the silicon sub-base 234 to provide a further better insulation effect. The material of the insulation layer 238 may be silicon dioxide, silicon nitride or ceramics, for example. In the present exemplary embodiment, the conductive leads 218a outwardly extends from the silicon sub-base 234 to an outer surface of the silicon base 202a directly, and the conductive leads 218a are not like the conductive leads 218 which outwardly extend from the side wall of the first cavity 208. Therefore, a portion of the insulation layer 238 and a portion of each conductive lead 218a are located in between the silicon cavity portion 236 and the silicon sub-base 234 of the silicon base 202a. With such design of the conductive lead 218a, the reflective surface in the first cavity 208 of the silicon base 202a is not affected by the conductive lead 218a to prevent an undesired reflective path of the light-emitting diode chip 212a from being formed so as to prevent the luminous efficiency from being reduced.

Such as shown in FIG. 6, the light-emitting diode chip 212a is disposed in the first cavity 208 of the silicon base 202a, and the light-emitting diode chip 212a may be disposed on the conductive lead 218a, for example. In the present exemplary embodiment, the side view type light-emitting diode package structure 200a has two light-emitting diode chips 212a. In other exemplary embodiments, the side view type light-emitting diode package structure 200a may include one single or more than two light-emitting diode chips 212a. Each light-emitting diode chip 212a includes two electrodes 222a, wherein the electrodes 222a have different conductivity types. For example, one of the electrodes 222a is P-type, and the other of the electrodes 222a N-type. In the present embodiment, the light-emitting diode chip 212a has a vertical electrode structure, i.e. the two electrodes 222a of the light-emitting diode chip 212a are respectively located on two opposite sides of the substrate of the light-emitting diode chip 212a. In order to match the design of multiple light-emitting diode chips 212a, the side view type light-emitting diode package structure 200a may include more than two conductive leads, such as three conductive leads 218a. In one embodiment, all electrodes 222a respectively correspond to the conductive leads 218a, and the electrodes 222a may be electrically connected to the corresponding conductive leads through the wires 226. Such as shown in FIG. 5, in one exemplary embodiment, a common cathode or common anode design may be adopted, so that the amount of the whole electrodes 222a of the side view type light-emitting diode package structure 200a is larger than that of the conductive leads 218a, and the conductive leads 218a are electrically connected to the two electrodes 222a respectively in the two light-emitting diode chips 212a via two wires 226. The light-emitting diode chips 212a may be light-emitting diode chips of the same color tone, for example, all light-emitting diode chips 212a may be blue light-emitting diode chips. The light-emitting diode chips 212a may include light-emitting diode chips of different color tones, for example, the light-emitting diode chips 212a may include two green light-emitting diode chips, one red light-emitting diode chip and one blue light-emitting diode chip.

In one exemplary embodiment, such as shown in FIG. 6, according to the brightness requirement of the product, the side view type light-emitting diode package structure 200a may selectively include a reflective layer 220 covering a side surface of the first cavity 208 of the silicon base 202a. The reflective layer 220 may be a metal reflective layer, a nonmetal reflective layer or a metal layer/nonmetal layer compound structure. Similarly, the side surface of the first cavity 208 may be directly used as a reflective surface without setting a reflective layer. The package encapsulant 228 is filled in the first cavity 208 of the silicon base 202a and covers the light-emitting diode chips 212a and the wires 226. In one exemplary embodiment, the package encapsulant 228 may be mixed with fluorescent powder. The choice of the fluorescent powder may be made according to the desired color of the light of the device and the color of the light emitted by the light-emitting diode chip 212a. In one embodiment, when the desired color of the light of the device is white, and the light-emitting diode chip 212a emits blue light, the package encapsulant 228 may be mixed with yellow fluorescent powder, or red-green fluorescent powder.

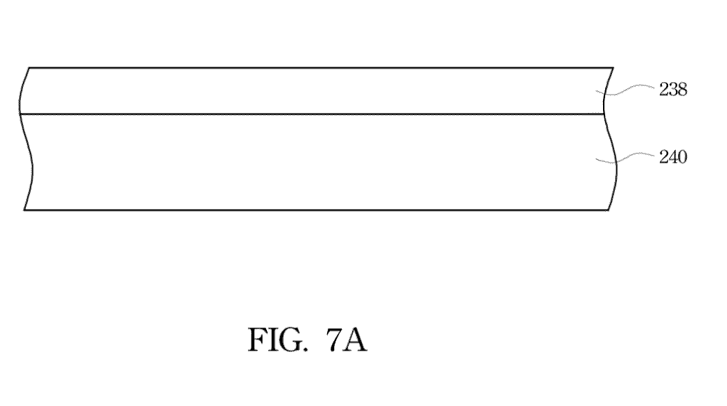

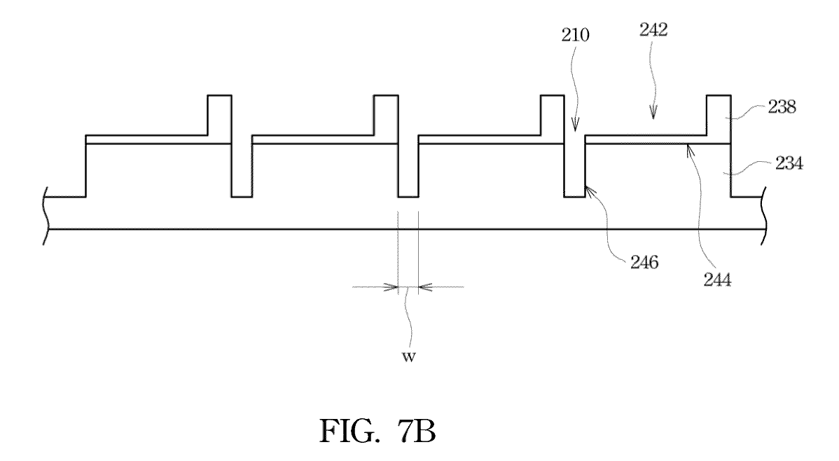

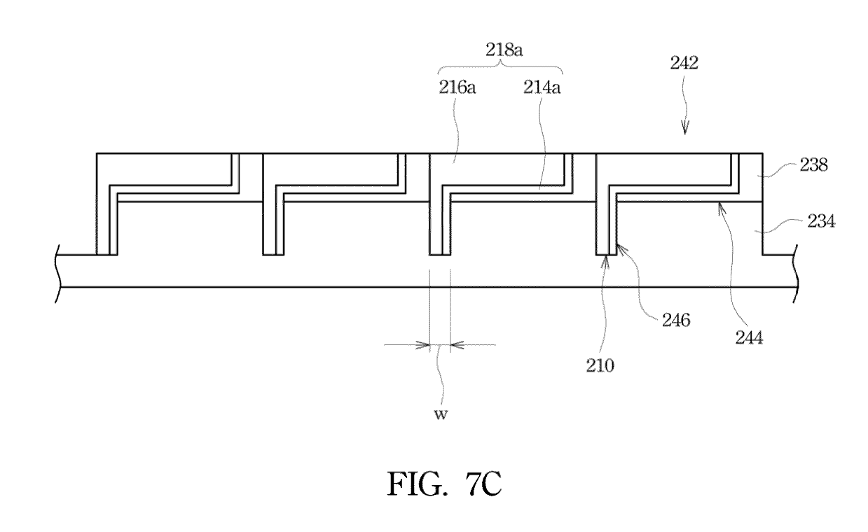

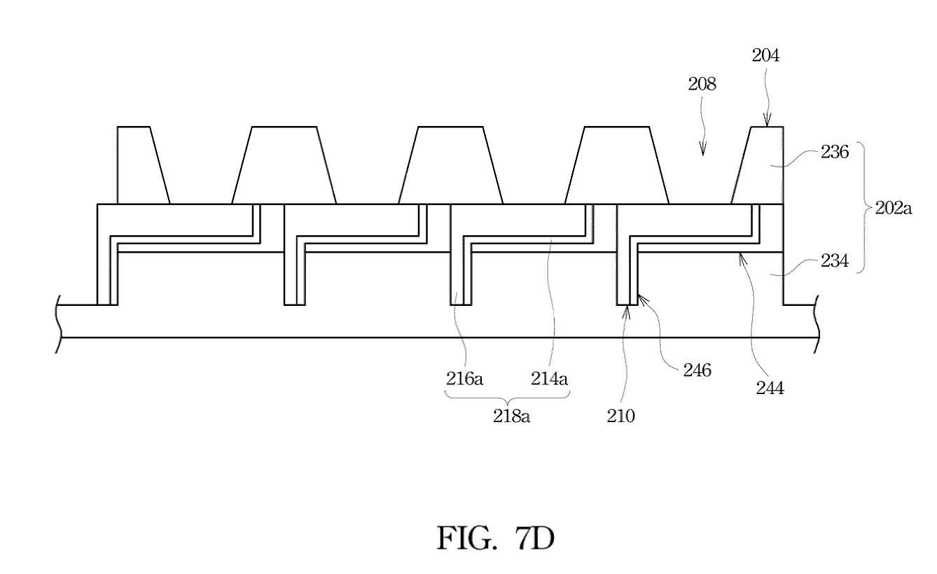

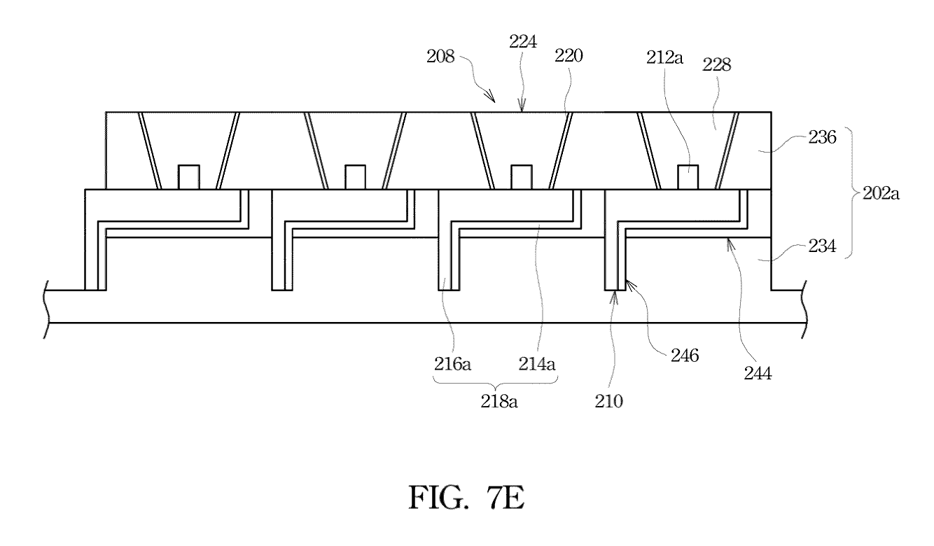

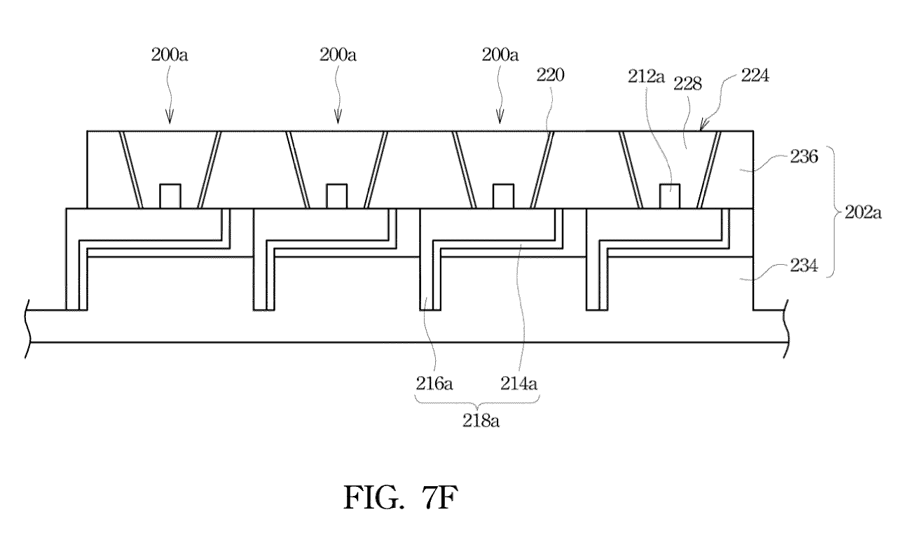

Refer to FIG. 7A through FIG. 7F. FIG. 7A through FIG. 7F are schematic flow diagrams showing a process of manufacturing a side view type light-emitting diode package structure in accordance with another preferred embodiment of the present invention. In one exemplary embodiment, in the manufacture of the side view type light-emitting diode package structure 200a, a silicon substrate 240 is provided. Next, such as shown in FIG. 7A, in order to provide better insulation between the silicon base 202a and the light-emitting diode chip 212a (referring to FIG. 7E), an insulation layer 238 may be selectively formed to cover a surface of the silicon substrate 240. Silicon dioxide or silicon nitride may be formed by, for example, a deposition method or a furnace thermal oxidation method to be used as the insulation layer 238, or a ceramic layer may be formed by, for example, a deposition method to be used as the insulation layer 238. A better heat-conducting effect can be provided by using the ceramic layer as the insulation layer. The thickness of the insulation layer 238 is preferably larger than that of the conductive lead 218a.

Next, such as shown in FIG. 7B, disposition regions 242 and the desired thickness of the conductive leads 218a (referring to FIG. 7C) to be formed are defined on the insulation layer 238 by, for example, a photolithography and etching method. Then, one or more second cavities 210 are defined in the silicon substrate 240 by, for example, a photolithography and etching method to define the disposition regions 242 of the conductive leads 218a and a plurality of silicon sub-bases 234. When the silicon substrate 240 is etched, a dry etching process, such as a reactive ion etching process, may be used. Each silicon sub-base 234 includes surfaces 244 and 246 adjacent to each other, wherein the insulation layer 238 is located on the surface 244 of the silicon sub-base 234. A portion of the second cavity 210 is located in the surface 246 of the silicon sub-base 234, and the second cavity 210 has a width w. The thickness of the conductive lead 218a formed sequentially may be controlled by controlling the width w of the second cavity 210. In the embodiment without insulation layer 238, the silicon substrate 240 is directly defined to form one or more second cavities 210 by, for example, a photolithography and etching method, so as to form the disposition regions 242 of the conductive leads 218a and a plurality of silicon sub-bases 234.

Next, referring to FIG. 7C, at least two conductive leads 218a are formed to cover the disposition regions 242 in the insulation layer 238 and to extend and cover the second cavity 210 in the surface 246 of the silicon sub-base 234. The conductive leads 218a are electrically isolated from each other. In one embodiment, each conductive lead 218a may be a single-layered structure. In one exemplary embodiment, each conductive lead 218a may be a multi-layered structure. For example, a thin seed layer 214a is firstly formed to cover the insulation layer 238 on the surface 244 of the silicon sub-base 234 and the surface of the second cavity 210 of the silicon sub-base 234 by a pattern defining technique and a sputtering or evaporation deposition method in the semiconductor process. The seed layer 214a includes two or more portions defined by a semiconductor pattern defining technique, and the portions are electrically isolated from each other. Then, an electroplating layer 216a is formed on the seed layer 214a by using the seed layer 214a as the base and using, for example, an electroplating method, to complete the conductive leads 218a electrically isolated from each other. The thickness of the seed layer 214a may be adjusted according to the process and may be controlled between about hundreds of Å and about thousands of Å. The material of the seed layer 214a may be, for example, Cu, Au, Ag or Ni. The thickness of the electroplating layer 216a may be controlled by using the width w of the second cavity 210 defined in the silicon sub-base 234, and is preferably slightly less than the width w to benefit the sequential cutting and dividing process of the package base. The material of the electroplating layer 216a may be, for example, Cu, Ag or Ni. In the present exemplary embodiment, the conductive leads 218a are formed by an electroplating method to prevent the material stress issue caused by bending the metal material many times in the prior art. In some embodiments, the conductive leads 218a with the desired thickness may be directly grown by, for example, a sputtering or evaporation method, and the electroplating process is not needed.

Then, such as shown in FIG. 7D, a silicon cavity portion 236 is disposed on the surface 244 of the silicon sub-base 234, and the surface 244 of the silicon sub-base 234 is bonded to the bottom surface of the silicon cavity portion 236 to form the silicon base 202a. In one embodiment, an adhesion layer (not shown) may be selectively used to connect the silicon cavity portion 236 and the silicon sub-base 234. The material of the adhesion layer may be polymer or adhesion glue, such as epoxy. Referring to FIG. 5 and FIG. 7D simultaneously, in the silicon base 202a, the silicon sub-base 234 and the silicon cavity portion 236 define the first cavity 208. The first cavity 208 exposes a portion of each conductive lead 218a.

Then, referring to FIG. 5 and FIG. 7E simultaneously, one or more light-emitting diode chips 212a are disposed in the first cavity 208 of each silicon base 202a. Each light-emitting diode chip 212a includes two electrodes 222a of different conductivity types, and the electrodes 222a are respectively disposed on two opposite sides of the light-emitting diode chip 212a. Next, the electrodes 222a are electrically connected to the corresponding conductive leads 218a by a flip-chip method or a wire bonding method with the use of the wires 226 shown in FIG. 5, for example. As the above description in accordance with FIG. 5, each conductive lead 218a is electrically connected to one or more electrodes 222a correspondingly. Next, according to the brightness requirement of the product, the reflective layer 220 may be selectively formed to cover the side surface of the first cavity 208 of the silicon base 202a, or the side surface of the first cavity 208 can be directly used as the reflective surface without forming a reflective layer. Then, the package encapsulant 228 is formed to fill in the first cavity 208 of the silicon base 202a and to cover the light-emitting diode chips 212a and the wires 226. In one embodiment, the package encapsulant 228 may be mixed with fluorescent powder, such as yellow fluorescent powder or red and green fluorescent powder. Sequentially, such as shown in FIG. 7F, a portion of the silicon cavity portion 236 and a portion of the silicon sub-base 234 are removed respectively from the top of the silicon cavity portion 236 and the bottom of the silicon sub-base 234 by using the conductive lead 218a as the etching stop layer and using, for example, a dry etching method to separate the side view type light-emitting diode package structures 200a, so as to form the structure shown in FIG. 5 and FIG. 6. In the present exemplary embodiment, the light-extracting surface 224 of the side view type light-emitting diode package stricture 200a is substantially perpendicular to the portion of the conductive lead 218a extending to the surface 206 on the outer side of the silicon based 202a.

According to the aforementioned exemplary embodiments, the side view type light-emitting diode package structure includes the following advantages. The expansion coefficient of silicon base is closer to that of the semiconductor material of the light-emitting diode chip, so that it can prevent the connection of the light-emitting diode chip and the silicon base from being affected by the thermal expansion to increase the reliability of the side view type light-emitting diode package structure. In addition, the silicon base has a superior heat-conducting ability, so that a conventional lead frame including a metal heat sink and having a highly irregular thickness is not needed, thereby greatly reducing the difficulty of manufacturing the lead frame and solving the scrap issue occurred in the process of manufacturing the lead frame. Furthermore, a silicon base has a superior heat-conducting property, so that the package structure is suitable for a low-power light-emitting diode chip and a high-power light-emitting diode chip of more than 1 W. Moreover, the cavity surface of a silicon base is smooth when formed using a semiconductor process, so that the surface of the cavity can be used as a reflective surface directly, the reflective effect of the reflective surface is not affected by the plasma cleaning, and the silicon base has a better reflective effect than the conventional plastic base.

The aforementioned side view type light-emitting diode package structures can be applied in a light-emitting diode light bar and a light-emitting diode backlight module. The light-emitting diode package structures are side view type, so that the width of the light-emitting diode light bar and the thickness of the side-edged type backlight module can be effectively reduced.

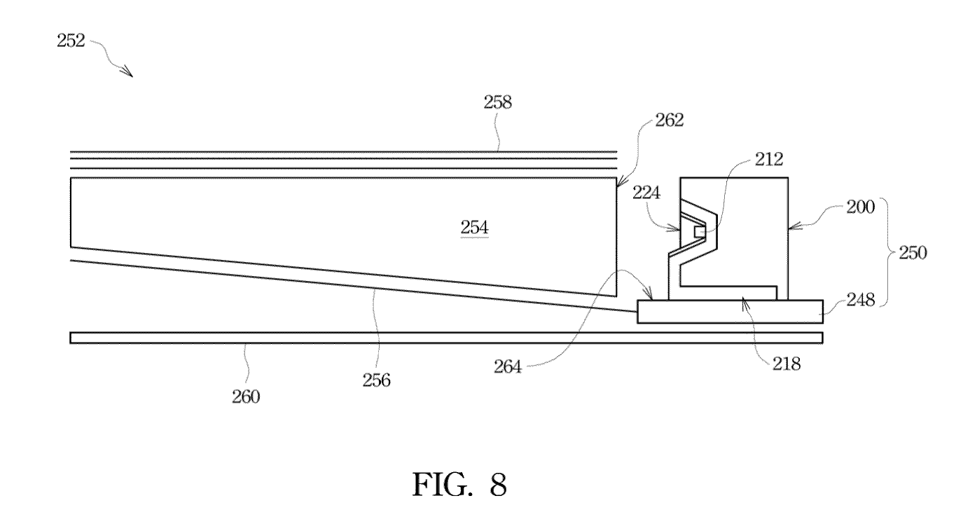

Refer to FIG. 8. FIG. 8 is a schematic diagram showing a light-emitting diode backlight module in accordance with a preferred embodiment of the present invention. A light-emitting diode backlight module 252 mainly includes a carrier 260, a light guide plate 254 and at least one light-emitting diode light bar 250. The carrier 260 may be a frame structure or a plate structure. The material of the carrier 260 may be metal or a hard plastic material to provide support with sufficient strength. The light guide plate 254 is disposed on the carrier 260. In the present exemplary embodiment, the light guide plate 254 is a wedge-shaped plate with an uneven thickness. Certainly, the light-emitting diode backlight module 252 may adopt a flat light guide plate with a uniform thickness. The light-emitting diode light bar 250 is also disposed on the carrier 260 and is located beside a light-entering surface 262 of the light guide plate 254.

In the present exemplary embodiment, the light-emitting diode light bar 250 is an application of the side view type light-emitting diode package structure 200. Therefore, the light-emitting diode light bar 250 mainly includes at least one side view type light-emitting diode package structure 200 and a circuit board 248. The side view type light-emitting diode package structure 200 is disposed on a plane surface 264 of the circuit board 248, and the conductive leads 218 of the side view type light-emitting diode package structure 200 are attached to the plane surface 264 of the circuit board 248. The plane surface 264 of the circuit board 248 is preset with a circuit, and the conductive leads 218 are electrically connected to the circuit preset on the plane surface 264 of the circuit board 248 to further electrically connect the light-emitting diode chip 212 in the side view type light-emitting diode package structure 200 to the circuit board 248. In the light-emitting diode light bar 250, the light-extracting surface 224 of the side view type light-emitting diode package structure 200 is substantially perpendicular to the plane surface 264 of the circuit board 248. In addition, when the light-emitting diode light bar 250 is applied in the light-emitting diode backlight module 252, the light-extracting surface 224 of the side view type light-emitting diode package structure 200 of the light-emitting diode light bar 250 is opposite to the light-entering surface 262 of the light guide plate 254.

In one exemplary embodiment, according to the brightness requirement of the product, the light-emitting diode backlight module 252 may selectively include a reflective sheet 256 disposed between the light guide plate 254 and the carrier 260. In addition, the light-emitting diode backlight module 252 may selectively include one or more optical films, such as a brightness enhancement film and a diffusion sheet, to enhance the optical quality of the light-emitting diode backlight module 252.

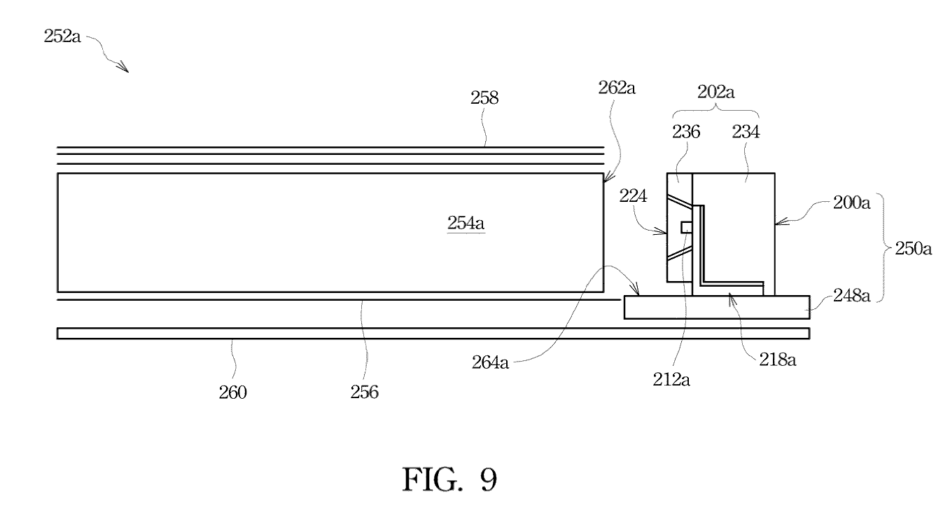

Refer to FIG. 9. FIG. 9 is a schematic diagram showing a light-emitting diode backlight module in accordance with another preferred embodiment of the present invention. A light-emitting diode backlight module 252a mainly includes a carrier 260, a light guide plate 254a and at least one light-emitting diode light bar 250a. The light guide plate 254a is disposed on the carrier 260. In the present exemplary embodiment, the light guide plate 254a is a flat light guide plate with a uniform thickness. However, the aforementioned wedge-shaped light guide plate 254 with an uneven thickness may be adopted in the light-emitting diode backlight module 252a. The light-emitting diode light bar 250a is also disposed on the carrier 260 and is located beside a light-entering surface 262a of the light guide plate 254a.

In the present exemplary embodiment, the light-emitting diode light bar 250a is an application of the side view type light-emitting diode package structure 200a. Therefore, the light-emitting diode light bar 250a mainly includes at least one side view type light-emitting diode package structure 200a and a circuit board 248a. The side view type light-emitting diode package structure 200a is disposed on a plane surface 264a of the circuit board 248a, and the conductive leads 218a of the side view type light-emitting diode package structure 200a are attached to the plane surface 264a of the circuit board 248a. The plane surface 264a of the circuit board 248a is preset with a circuit, and the conductive leads 218a are electrically connected to the circuit preset on the plane surface 264a of the circuit board 248a to further electrically connect the light-emitting diode chip 212a in the side view type light-emitting diode package structure 200a to the circuit board 248a. In the light-emitting diode light bar 250a, the light-extracting surface 224 of the side view type light-emitting diode package structure 200a is substantially perpendicular to the plane surface 264a of the circuit board 248a. When the light-emitting diode light bar 250a is applied in the light-emitting diode backlight module 252a, the light-extracting surface 224 of the side view type light-emitting diode package structure 200a of the light-emitting diode light bar 250a is opposite to tie light-entering surface 262a of the light guide plate 254a.

In one exemplary embodiment, according to the brightness requirement of the product, the light-emitting diode backlight module 252a may selectively include a reflective sheet 256 disposed between the light guide plate 254a and the carrier 260. In addition, the light-emitting diode backlight module 252a may selectively include one or more optical films, such as a brightness enhancement film and a diffusion sheet, to enhance the optical quality of the light-emitting diode backlight module 252a.

As is understood by a person skilled in the art, the foregoing embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A side view type light-emitting diode package structure, including:
a silicon base with a first cavity, wherein the first cavity defines a light-extracting surface of the side view type light-emitting diode package structure;
a first conductive lead disposed at least on a portion of the first cavity and extending to an outer surface of the silicon base;
a second conductive lead disposed at least on another portion of the first cavity and extending to the outer surface of the silicon base, wherein the first conductive lead and the second conductive lead are electrically isolated from each other; and
a first light-emitting diode chip including a first electrode and a second electrode, wherein the first electrode and the second electrode are electrically connected to the first conductive lead and the second conductive lead respectively,
wherein the outer surface of the silicon base is substantially perpendicular to the light-extracting surface.

2. The side view type light-emitting diode package structure according to claim 1, wherein the silicon base includes:
a silicon cavity portion; and
a silicon sub-base connected to a bottom surface of the silicon cavity portion, wherein the first cavity is defined by the silicon cavity portion and the silicon sub-base.

3. The side view type light-emitting diode package structure according to claim 1, wherein each of the first conductive lead and the second conductive lead is a multi-layered structure.

4. The side view type light-emitting diode package structure according to claim 1, further including at least one second light-emitting diode chip, wherein the second light-emitting diode chip includes two third electrodes of different conductivity types.

5. The side view type light-emitting diode package structure according to claim 4, further including two third conductive leads of different conductivity types, wherein the conductive types of the third conductive leads respectively correspond to the conductivity types of the third electrodes, and the third conductive leads are electrically connected to the corresponding third electrodes respectively.

6. The side view type light-emitting diode package structure according to claim 4, further including a third conductive lead, wherein one of the third electrodes is electrically connected to the third conductive lead, the other one of the third electrodes has a conductivity type the same as a conductivity type of the first electrode, and the other one of the third electrodes is electrically connected to the first conductive lead.

7. The side view type light-emitting diode package structure according to claim 1, further including a package encapsulant covering the first light-emitting diode chip, wherein the package encapsulant includes fluorescent powder.

8. A method for manufacturing a side view type light-emitting diode package structure, including:
providing a silicon base, wherein the silicon base includes a first cavity and a second cavity respectively set in a first surface and a second surface of the silicon base adjacent to each other, and the first cavity defines a light-extracting surface of the side view type light-emitting diode package structure;
forming at least two conductive leads to cover the first cavity and to extend on the second cavity, wherein the at least two conductive leads are electrically isolated from each other, and the light-extracting surface is substantially perpendicular to the portions of the at least two conductive leads located in the second cavity;
disposing at least one light-emitting diode chip in the first cavity, wherein the at least one light-emitting diode chip includes two electrodes electrically connected to the at least two conductive leads respectively; and
forming a package encapsulant to cover the at least one light-emitting diode chip.

9. The method for manufacturing a side view type light-emitting diode package structure according to claim 8, wherein the step of forming each of the at least two conductive leads further includes:
forming a seed layer on the silicon base; and
forming an electroplating layer on the seed layer.

10. The method for manufacturing a side view type light-emitting diode package structure according to claim 8, wherein the at least one light-emitting diode chip includes a plurality of light-emitting diode chips, and each of the light-emitting diode chips includes two electrodes.

11. The method for manufacturing a side view type light-emitting diode package structure according to claim 10, wherein the at least two conductive leads includes more than two conductive leads.

12. A method for manufacturing a side view type light-emitting diode package structure, including:
providing a silicon sub-base, wherein the silicon sub-base includes a first surface and a second surface adjacent to each other, and the silicon sub-base includes a first cavity located in the second surface;
forming at least two conductive leads to cover and to extend on the first surface of the silicon sub-base and a surface of the first cavity, wherein the at least two conductive leads are electrically isolated from each other;
disposing a silicon cavity portion on the first surface of the silicon sub-base, wherein the silicon sub-base and the silicon cavity portion define a second cavity, the second cavity exposes a portion of each of the at least two conductive leads, the second cavity defines a light-extracting surface of the side view type light-emitting diode package structure, and the light-extracting surface is substantially perpendicular to portions of the at least two conductive leads located in the first cavity;
disposing at least one light-emitting diode chip in the second cavity, wherein the at least one light-emitting diode chip includes two electrodes electrically connected to the at least two conductive leads respectively; and
forming a package encapsulant to cover the at least one light-emitting diode chip.

13. The method for manufacturing a side view type light-emitting diode package structure according to claim 12, wherein the step of providing the silicon sub-base includes:
providing a silicon substrate; and
etching the silicon substrate to form the first cavity.

14. The method for manufacturing a side view type light-emitting diode package structure according to claim 12, wherein the step of providing the silicon sub-base includes:
providing a silicon substrate;
forming an insulation layer to cover a surface of the silicon substrate;
performing a definition step on the insulation layer to define a disposition region on the insulation layer; and
etching the silicon substrate to form the first cavity.

15. The method for manufacturing a side view type light-emitting diode package structure according to claim 12, wherein the step of forming each of the at least two conductive leads further includes:
forming a seed layer on the first surface of the silicon sub-base and the surface of the first cavity; and
forming an electroplating layer on the seed layer.

16. A light-emitting diode light bar, including:
a circuit board; and
at least one side view type light-emitting diode package structure, including:
a silicon base including a first cavity, wherein the first cavity defines a light-extracting surface of the side view type light-emitting diode package structure;
a first conductive lead disposed at least on a portion of the first cavity and extending to an outer surface of the silicon base;
a second conductive lead disposed at least on another portion of the first cavity and extending to the outer surface of the silicon base, wherein the first conductive lead and the second conductive lead are electrically isolated from each other, the first conductive lead and the second conductive lead are located on a plane surface of the circuit board, and the light-extracting surface is substantially perpendicular to the plane surface of the circuit board; and
a first light-emitting diode chip including a first electrode and a second electrode, wherein the first electrode and the second electrode are electrically connected to the first conductive lead and the second conductive lead respectively.

17. The light-emitting diode light bar according to claim 16, wherein the silicon base includes:
a silicon cavity portion; and
a silicon sub-base connected to a bottom surface of the silicon cavity portion, wherein the first cavity is defined by the silicon cavity portion and the silicon sub-base.

18. The light-emitting diode light bar according to claim 17, wherein the side view type light-emitting diode package structure further includes an insulation layer disposed between the first conductive lead and the second conductive lead, and the silicon base, and a portion of the insulation layer and a portion of each of the first conductive lead and the second conductive lead are located in between the silicon cavity portion and the silicon sub-base.

19. A light-emitting diode backlight module, including:
a carrier;
a light guide plate disposed on the carrier; and
at least one light-emitting diode light bar disposed beside a light-entering surface of the light guide plate, wherein the at least one light-emitting diode light bar includes:
a circuit board; and
at least one side view type light-emitting diode package structure, including:
a silicon base including a first cavity, wherein the first cavity defines a light-extracting surface of the side view type light-emitting diode package structure;
a first conductive lead disposed at least on a portion of the first cavity and extending to an outer surface of the silicon base;
a second conductive lead disposed at least on another portion of the first cavity and extending to the outer surface of the silicon base, wherein the first conductive lead and the second conductive lead are electrically isolated from each other, the first conductive lead and the second conductive lead are located on a plane surface of the circuit board, the light-extracting surface is opposite to the light-entering surface, and the light-extracting surface is substantially perpendicular to the plane surface of the circuit board; and
a first light-emitting diode chip including a first electrode and a second electrode, wherein the first electrode and the second electrode are electrically connected to the first conductive lead and the second conductive lead respectively.

20. The light-emitting diode backlight module according to claim 19, wherein the silicon base includes:
a silicon cavity portion; and
a silicon sub-base connected to a bottom surface of the silicon cavity portion, wherein the first cavity is defined by the silicon cavity portion and the silicon sub-base.
